(19) United States
(12) Patent Application Publication
(10) Pub. No.: US 2016/0134243 A1
(43) Pub. Date: May 12, 2016

(54) BIAS-BOOSTING CIRCUIT WITH DUAL CURRENT MIRRORS FOR RF POWER AMPLIFIER

(71) Applicant: Morfis Semiconductor, Inc., Irvine, CA (US)

(72) Inventors: Sifen Luo, Irvine, CA (US); Changli Chen, Irvine, CA (US)

(21) Appl. No.: 14/932,878

(22) Filed: Nov. 4, 2015

Related U.S. Application Data
(60) Provisional application No. 62/076,395, filed on Nov. 6, 2014.

(51) Int. Cl. H03F 1/02; H03F 3/21; H03F 3/193; H03F 1/56

(52) U.S. Cl. CPC H03F 1/0205; H03F 1/56; H03F 3/21; H03F 3/193; H03F 2200/451; H03F 2200/555

(57) ABSTRACT

An RF power amplifier circuit has a signal input and a signal output. An input matching network connected to the signal input, and an output matching network is connected to the signal output. There is a power amplifier with an input connected to the input matching network, and an output connected to the output matching network. A bias boosting circuit is connected to the input of the power amplifier, and the bias boosting circuit comprises a cascode current mirror that is defined by a first cascode circuit and a second cascode circuit, and a biasing transistor that is connected to an output of the cascode current mirror. The biasing transistor, together with the power amplifier, defines a current mirror. The bias boosting circuit is thus a dual current mirror circuit that boosts the bias of the power amplifier.

### CROSS-REFERENCE TO RELATED APPLICATIONS

This application relates to and claims the benefit of U.S. Provisional Application No. 62/076,395, filed Nov. 6, 2014 and entitled “BIAS-BOOSTING CIRCUIT WITH DUAL CURRENT MIRRORS FOR RF POWER AMPLIFIER” the entirety of the disclosure of which is wholly incorporated by reference herein.

### STATEMENT RE: FEDERALLY SPONSORED RESEARCH/DEVELOPMENT

Not Applicable

### BACKGROUND

1. Technical Field

The present disclosure relates generally to radio frequency (RF) integrated circuits, and more particularly, to bias-boosting circuits with dual current minors for RF power amplifiers.

2. Related Art

Wireless communications systems find applications in numerous contexts involving information transfer over long and short distances alike, and there exists a wide range of modalities suited to meet the particular needs of each. Generally, wireless communications involve an RF carrier signal that is variously modulated to represent information, and the modulation, transmission, receipt, and demodulation of the signal conform to a set of standards for the coordination of the same.

Many different wireless communications technologies or air interfaces are known in the art, including GSM (Global System for Mobile communications), EDGE (Enhanced Data rates for GSM Evolution), UMTS (Universal Mobile Telecommunications System), and 4G LTE (Long Term Evolution). Additionally, local area data networking modalities such as Wireless LAN or WLAN (IEEE 802.11-series) are also widely utilized.

A fundamental component of any wireless communications system is the transceiver, that is, the combined transmitter and receiver circuitry. The transceiver encodes the data to a baseband signal and modulates it with an RF carrier signal. Upon receipt, the transceiver down-converts the RF signal, demodulates the baseband signal, and decodes the data represented by the baseband signal. An antenna connected to the transmitter converts the transmitted electrical signals to electromagnetic waves, as well as the received electromagnetic waves back to electrical signals. Typical transceivers do not generate sufficient power or have sufficient sensitivity in itself for reliable communications. Thus, additional conditioning of the RF signal is necessary. The circuitry between the transceiver and the antenna that provide such functionality is referred to as the front end module, which includes a power amplifier for increased transmission power, and/or a low noise amplifier for increased receive sensitivity.

In modern communications modalities/air interfaces mentioned above, the peak-to-average power ratio (PAPR) of the signals is high. For example, in a W-CDMA modulation scheme, the peak-to-average power ratio of the signals may be as high as 3.5 dB. In order to properly handle signals with such high peak-to-average power ratios, conventional designs utilize large transistors in the power amplifier circuitry. The biasing circuit for the power amplifier transistors is oftentimes a simple current mirror architecture, but there are several notable disadvantages. In particular, such power amplifiers may exhibit gain compression at high signal levels because of a voltage drop (I*R) across bipolar transistors, or because of a fixed voltage bias in field effect transistors.

Accordingly, there is a need in the art for an improved bias-boosting circuit that overcomes early gain compression in power amplifiers. There is also a need in the art for a bias-boosting circuit that extends the 1 dB compression point (P1dB) to a higher power level while maintaining the quiescent current of the power amplifier transistor at a relatively low level.

### BRIEF SUMMARY

The present disclosure is directed to a dual current-minor circuit that provides a bias boost for power amplifier transistors. In accordance with various embodiments, a balance between power amplifier efficiency and linearity is maintained.

One embodiment contemplates an RF power amplifier circuit with a signal input and a signal output. There may be an input matching network that is connected to the signal input, along with an output matching network that is connected to the signal output. Furthermore, RF power amplifier circuit may include a power amplifier with an input and an output. The input may be connected to the input matching network, and the output may be connected to the output matching network. There may also be a bias boosting circuit that is connected to the input of the power amplifier. The bias boosting circuit may comprise a cascode current mirror that is defined by a first cascode circuit and a second cascode circuit. Furthermore, the bias boosting circuit may include a biasing transistor that is connected to an output of the cascode current mirror. The biasing transistor, together with the power amplifier, may define a current mirror.

Another embodiment of the present disclosure contemplates a dual current minor circuit for biasing a power amplifier. The circuit may include a first cascode circuit with a first transistor and a second transistor. Each of these transistors may include a respective gate terminal, source terminal, and drain terminal. In accordance with the cascode configuration, the source terminal of the first transistor and the drain terminal of the second transistor may be connected and define a common node. Additionally, the circuit may include a second cascode circuit with a third transistor and a fourth transistor. Each of these transistors may likewise include a respective gate terminal, source terminal, and drain terminal. The dual current minor circuit may also incorporate a biasing transistor that has a gate terminal that is connected to the common node. The biasing transistor may also define a current minor with a transistor of the power amplifier. There may additionally be a supply terminal that is connectible to a voltage source. The supply terminal may be connected to the drain terminals of each of the second transistor, the fourth transistor, and the biasing transistor.

The present invention will be best understood by reference to the following detailed description when read in conjunction with the accompanying drawings.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is an exemplary power amplifier circuit that may incorporate a bias boosting circuit in accordance with various embodiments of the present disclosure;

FIG. 2 is a first embodiment of the bias boosting circuit with dual current minors;

FIG. 3 is a second embodiment of the bias boosting circuit with dual current mirrors;

FIG. 4 plots a simulated gain curve as a function of output power for the power amplifier circuit of FIG. 1 incorporating the bias boosting circuit as contemplated in the present disclosure in comparison to a gain curve of a simple current mirror circuit;

FIG. 5 plots simulated AM-PM characteristics of the power amplifier circuit of FIG. 1 incorporating the bias boosting circuit in comparison to the AM-PM characteristics of a simple current mirror circuit.

### DETAILED DESCRIPTION

The detailed description set forth below in connection with the appended drawings is intended as a description of the several presently contemplated embodiments of bias boosting circuits with dual current minors for RF power amplifiers, and is not intended to represent the only form in which the disclosed invention may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

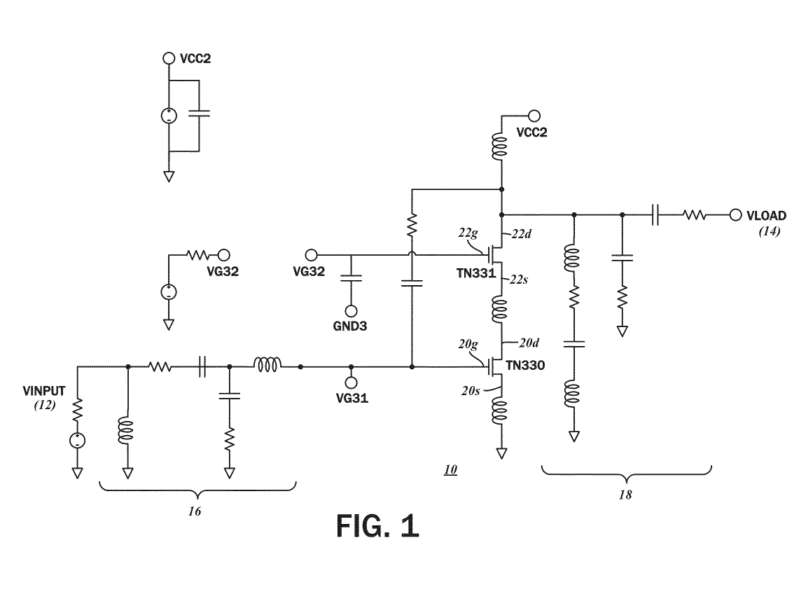

The schematic diagram of FIG. 1 illustrates one embodiment of a power amplifier circuit 10 in accordance with the present disclosure. Generally, the power amplifier circuit 10 has a stacked transistor configuration with a first power amplifier transistor TN330 and a second power amplifier transistor TN331. In a preferred, though optional embodiment, the first power amplifier transistor TN330 and the second power amplifier transistor TN331 are complementary metal oxide semiconductor (CMOS) field effect transistors (FETs) as particularly illustrated in the schematic diagram, though this is by way of example only and not of limitation. With the first power amplifier transistor TN330 and the second power amplifier transistor TN331 being field effect transistors, each is understood to include a gate terminal, a source terminal, and a drain terminal. To the extent other types of transistors are utilized, it will be understood that corresponding counterparts thereof are deemed to be encompassed within the scope of the present disclosure.

The power amplifier circuit 10 is generally defined by a signal input 12 that is connectable to an RF signal source, along with a signal output 14 connectable to a load (such as an antenna). The signal input 12 is connected to an input matching network 16, an output of which is connected to the power amplifier transistors, more specifically, a gate terminal of the first power amplifier transistor TN330. The output from the power amplifier transistors is connected to an output matching network 18, which in turn is connected to the signal output 14. As will be recognized by those having ordinary skill in the art, the input matching network 16 and the output matching network 18 are comprised of various inductive, capacitive, and resistive elements to impedance match the power amplifier transistors to signal source components (in the case of the input matching network 16) and load components (in the case of the output matching network 18). The configuration and optimization of the input matching network 16 and the output matching 18 are within the purview of one of ordinary skill in the art, so for the sake of brevity, additional details thereof are omitted.

Again, with the stacked transistor configuration, the signal input from the input matching network 16 connected to a gate terminal 20g of the first power amplifier transistor TN330. The source terminal 20s of the first power amplifier transistor TN330 is tied to ground, and a drain terminal 20d of the first power amplifier transistor TN330 is connected to the second power amplifier transistor TN331, specifically the source terminal 22s thereof. A drain terminal 22d of the second power amplifier transistor TN331 is connected to the output matching network 18, along with a voltage source VCC2. The second power amplifier transistor TN331 is biased by the voltage source VG32, and thus the gate terminal 22g of the second power amplifier transistor TN331 is connected thereto. As will be described in further detail below, the first power amplifier transistor TN330 is biased by a separate bias boosting circuit 24, an output node of which is denoted as VG31. Thus, in addition to being connected to the input matching network 16, the gate terminal 20g of the first power amplifier transistor TN330 is also connected to VG31, as shown.

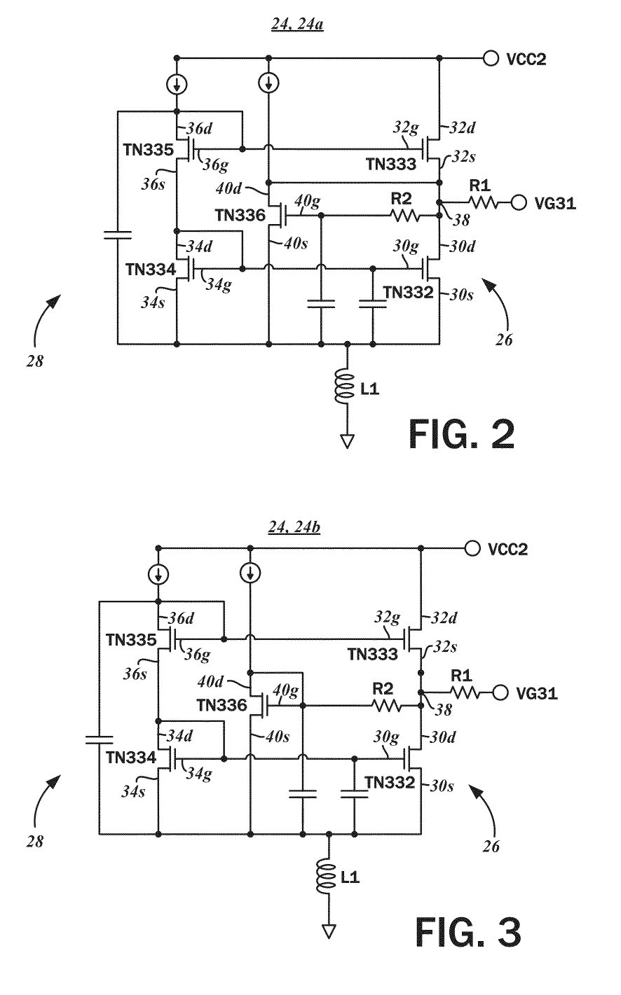

Referring now to the schematic diagram of FIG. 2, a first embodiment of the bias boosting circuit 24a generally has a cascode current minor configuration with a first cascode circuit 26 and a second cascode circuit 28. The first cascode circuit and the second cascode circuit 28 are interconnected to define a cascode current mirror. In further detail, the first cascode circuit 26 includes a first transistor TN332 and a second transistor TN333, and the second cascode circuit 28 includes a third transistor TN334 and a fourth transistor TN335. According to one embodiment of the present disclosure, the transistors in the cascode circuits 26, 28 are each N-channel metal oxide semiconductor (NMOS) field effect transistors, as shown.

In the first cascode circuit 26, the first transistor TN332 is operating as a common source, while the second transistor TN333 is operating source follower. That is, a source terminal 30s of the first transistor TN332 is connected to ground, and a gate terminal 30g of the first transistor TN332 and a gate terminal 32g of the second transistor TN333 are biased by the second cascode circuit 28. In the second cascode circuit 28, the third transistor TN334 and the fourth transistor TN335 are operating as a diode connection string to provide bias voltage for the first cascode circuit 26. A source terminal 34s of the third transistor TN334 is likewise connected to ground, a drain terminal 36d is connected to a gate terminal 36g of the fourth transistor TN336, a source terminal 36s of the fourth transistor TN336 is connected a drain terminal 34d of the third transistor TN334, and a drain terminal 34d of the third transistor TN334 is connected to a gate terminal 34g of the same.

As indicated above, the first cascode circuit 26 and the second cascode circuit 28 are mirrored. In relation to the common source transistors, e.g., the first transistor TN332 and the third transistor TN334, the respective gate terminals 30g, 34g, are connected to each other. Likewise, the respective gate terminals 32g, 36g of the second transistor TN333 and the fourth transistor TN335 are connected to each other. The drain terminal 30d of the first transistor TN332 and the source terminal 32s of the second transistor TN333 are connected, and that junction defines a common node 38. Furthermore, the drain terminal 34d of the third transistor TN334 is connected to the source terminal 36s of the fourth transistor TN335. The drain terminal 36d of the fourth transistor TN335 is tied to the gate terminal 36g of the same, and likewise, the drain terminal 34d of the third transistor TN334 is tied to the gate terminal 34g of the same. The drain terminal 32d of the second transistor TN333 is connected to the voltage source VCC2, and the drain terminal 36d of the third transistor TN334 is connected to a current source.

In addition to the first cascode circuit 26 and the second cascode circuit 28, the bias boosting circuit 24 includes a biasing transistor TN336. The first power amplifier transistor TN330 and the biasing transistor TN336 define a simple current minor. This current minor, together with the cascode current minor defines a dual current mirror circuit to bias the power amplifier transistor, specifically the first power amplifier transistor TN330. A gate terminal 40g of the biasing transistor TN336 is connected to the common node 38 over an isolation resistor R2, which isolates the biasing transistor TN336 from the common node 38 and the first power amplifier transistor TN330. The drain terminal 40d of the biasing transistor TN336 is connected to another current source, while the source terminal 40s of the same is connected to ground.

Between the first power amplifier and the common node 38 is a biasing transistor R1. Accordingly, the biasing transistor R1 is connected to the isolation resistor R2, the source terminal 32s of the second transistor TN333, and the drain terminal 30d of the first transistor TN333. Values of the biasing transistor R1 may be adjusted to control the boosting level.

With the application of a large RF signal to the power amplifier, specifically at the gate terminal 20g of the first power amplifier transistor TN330, the AC voltage at the drain terminal of the first transistor TN332 may be zero volts or almost zero volts during the negative half cycle of the RF signal. Under these circumstances, the first transistor TN332 may be turned off, and a current from the source terminal 32s of the second transistor TN333 may charge the gate terminal 20g of the first power amplifier transistor TN330. During the positive half cycle of the signal, the AC voltage at the source terminal 32s of the second transistor TN333 may be higher than the voltage at the gate terminal 32g, thereby turning off the second transistor TN333. The first transistor TN332 accordingly discharges the gate terminal 20g of the first power amplifier transistor TN330. Because of the high and low impedances at the drain terminals 30d, 32d and source terminals 30s, 32s of the respective first transistor TN332 and second transistor TN333, there is a difference in the charging and discharging rates. This is understood to lead to charge accumulation at the gate terminal 20g of the first power amplifier transistor TN330, along with an increase in the average DC voltage level as the input RF signal level increases. It will be appreciated that this effectively boosts the gate voltage of the first power amplifier transistor TN330, and extends the 1 dB compression point (P1dB) of the power amplifier circuit 10. By so extending P1dB efficiency and linearity of the power amplifier circuit 10 is improved. For a given output power, a relatively smaller transistor or amplifier may be utilized, with attendant decreases in die area and cost.

An alternative, second embodiment of the bias boosting circuit 24b is shown in FIG. 3. Like the first embodiment 24a, the second embodiment of the bias boosting circuit 24b is comprised of the first cascode circuit 26 and the second cascode circuit 28. Further, the first cascode circuit 26 is defined by the first transistor TN332 in a common source operation and the second transistor TN333 as a source follower. The biasing transistor TN336, and specifically the gate terminal 40g thereof, is connected to the common node 38 over the isolation resistor R2. The source terminal 32s of the second transistor TN333 and the drain terminal 30d of the first transistor TN332 are also connected to the common node 38. However, instead of the drain terminal 40d of the biasing transistor TN336 being connected to the common node 38, it is connected to the gate terminal 40g of the biasing transistor TN336. The operation of the bias boosting circuit 24b is the same as the first embodiment 24a.

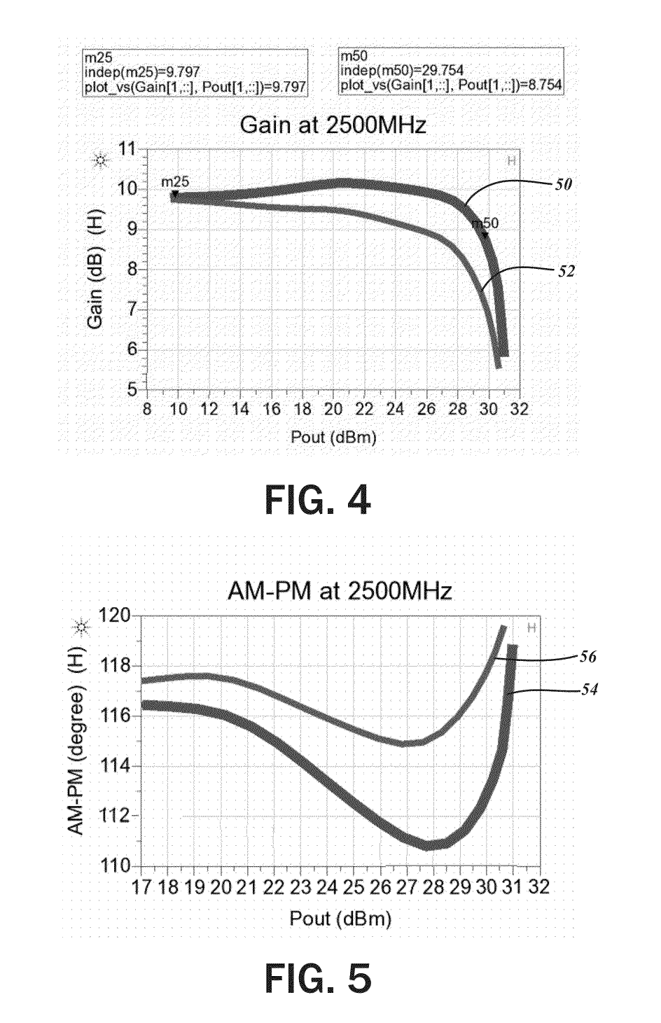

The graph of FIG. 4 plots a simulated gain curve of the power amplifier circuit 10 in accordance with various embodiments of the present disclosure. The gain curve is shown as a function of output power (in dBm), at an operating frequency of 2.5 GHz. Specifically, a first plot 50 shows the gain curve for the power amplifier circuit 10 that is biased with the bias boosting circuit 24, while a second plot 52 shows the gain curve of the same power amplifier circuit 10 that is biased with a simple current mirror circuit with a 1 kΩ isolation resistor. For both of these simulations, the amplifiers are biased with the same quiescent current. As shown in the first plot 50, with the output power levels between 10 dBm and 27 dBm, the gain remains approximately 10 dB. The gain drops by 1 dB at approximately 29.754 dBm output power. In comparison, as shown in the second plot, the gain steadily decreases between 10 dBm output power, by the point gain drops by 1 dB, the output power is approximately 26 dBm. Accordingly, the P1dB point is extended by approximately 3 dB.

The graph of FIG. 5 illustrate the phase distortion (AM-PM) characteristics of the power amplifier circuit 10. A first plot 54 corresponds to the power amplifier circuit 10 biased with the bias boosting circuit 24 in accordance with various embodiments of the present disclosure, and a second plot 56 corresponds to the power amplifier circuit 10 biased with the aforementioned simple current minor circuit. Both the first plot 54 and the second plot 56 show phase distortion in degrees as a function of output power (in dBm), at an operating frequency of 2.5 GHz. It is understood that phase distortion increases slightly in the power amplifier circuit 10 that is biased with the bias boosting circuit 24. Phase distortion may be increased, however, with reduced gain compression and increased output power, for better linearity and efficiency of the power amplifier circuit 10.

The particulars shown herein are by way of example and for purposes of illustrative discussion of the embodiments of the bias boosting circuit only and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

What is claimed is:

1. A radio frequency (RF) power amplifier circuit including a signal input and a signal output, comprising:
an input matching network connected to the signal input;
an output matching network connected to the signal output;
a power amplifier with an input connected to the input matching network and an output connected to the output matching network; and
a bias boosting circuit connected to the input of the power amplifier, the bias boosting circuit comprising a cascode current mirror defined by a first cascode circuit and a second cascode circuit, and a biasing transistor connected to an output of the cascode current mirror that defines a current mirror with the power amplifier.

2. The RF power amplifier circuit of claim 1, wherein the power amplifier has a stacked transistor configuration including a first transistor and a second transistor, a gate terminal of the first transistor being connected to the input matching network, a drain terminal of the second transistor being connected to the output matching network, and a drain terminal of the first transistor being connected to a source terminal of the second transistor.

3. The RF power amplifier circuit of claim 1, further comprising:
a voltage source connected to the drain terminal of the second transistor through an inductor.

4. The RF power amplifier circuit of claim 1, wherein the first cascode circuit includes a first transistor and a second transistor, a drain terminal of the first transistor and a source terminal of the second transistor defining a common node.

5. The RF power amplifier circuit of claim 4, wherein a gate terminal of the biasing transistor is connected to the common node.

6. The RF power amplifier circuit of claim 5, further comprising:
an isolation resistor connected between the gate terminal of the biasing transistor and the common node.

7. The RF power amplifier circuit of claim 5, further comprising:
a bias control resistor connected between the common node and the power amplifier, a value of the bias control resistor defining a bias boost level to the power amplifier.

8. The RF power amplifier circuit of claim 5, wherein a drain terminal of the biasing transistor is connected to the common node.

9. The RF power amplifier circuit of claim 5, wherein a drain terminal of the biasing transistor is connected to the gate terminal of the biasing transistor.

10. A dual current minor circuit for biasing a power amplifier, comprising:
a first cascode circuit with a first transistor and a second transistor each including a respective gate terminal, source terminal, and drain terminal, the drain terminal of the first transistor and the source terminal of the second transistor being connected and defining a common node;
a second cascode circuit with a third transistor and a fourth transistor each including a respective gate terminal, source terminal, and drain terminal;
a biasing transistor with a gate terminal connected to the common node, the biasing transistor defining a current minor with a transistor of the power amplifier;
a supply terminal connectible to a voltage source, the supply terminal being connected to the drain terminals of the second transistor of the first cascode circuit; and
a current supply connected to the drain terminal of the fourth transistor and the biasing transistor.

11. The circuit of claim 10, further comprising:
an isolation resistor connected to the gate terminal of the biasing transistor and the common node.

12. The circuit of claim 10, further comprising:
a bias control resistor connected to the common node and the power amplifier, a value of the bias control resistor defining a bias boost level.

13. The circuit of claim 10, wherein the drain terminal of the biasing transistor is connected to the common node.

14. The circuit of claim 10, wherein the drain terminal of the biasing transistor is connected to the gate terminal of the biasing transistor.
